(19) United States
(12) Patent Application Publication
(10) Pub. No.: US 2007/0008706 A1
(43) Pub. Date: Jan. 11, 2007

(54) Casing structure for an uninterrupted power supply

(76) Inventor: Vincent Lai, Taoyuan Hsien (TW)

Correspondence Address: PRO-TECHTOR INTERNATIONAL SERVICES, 20775 NORADA CT., SARATOGA, CA, 95070, US

(21) Appl. No.: 11/177,912

(22) Filed: Jul. 7, 2005

(51) Int. Cl. H05K 5/02

(52) U.S. Cl. 361/796; 361/797; 361/752; 361/801

(57) ABSTRACT

A casing structure for an uninterrupted power supply including a casing structured from left and right side panels, front and rear cover panels. Arc-shaped hook slots are respectively defined on upper and lower edges of rear sides of the left and right side panels, which mutually hook together to assemble the left and right side panels using a pivot-type method. Two sides of the front cover panel are respectively provided with catch slots, and front edges of the left and right side panels are respectively provided with catch strips, and the catch slots are used to slot onto the catch strips of the front cover panel, thereby completing assembly of the casing structure. Moreover, simply removing the front cover panel facilitates replacement of the battery in the casing structure.

### BACKGROUND OF THE INVENTION

(a) Field of the Invention

The present invention relates to an assembly structure for a pivot-type casing, and more particularly to a casing assembled by using a catch fastening method, which enables easy uninstalling and installing of a battery within the casing after removing a cover panel.

(b) Description of the Prior Art

An assembly method for a casing of a conventional uninterrupted power supply (UPS) generally uses a plurality of screws to fasten the casing together. However, assembly and disassembly of the casing is inconvenient, and the screws are easily lost. Moreover, when wanting to remove or install a battery in the casing, it is necessary to disassemble the entire casing, which not only takes time and energy, but is also extremely inconvenient to the user.

### SUMMARY OF THE INVENTION

A primary objective of the present invention is to provide a casing structure for an uninterrupted power supply that can be assembled from left and right side panels and front and rear cover panels using a pivot-type catch fastening method, which enables rapid and simple assembly and disassembly of the casing structure. Moreover, simply removing the front cover panel facilitates replacement of the battery in the casing structure.

To enable a further understanding of said objectives and the technological methods of the invention herein, brief description of the drawings is provided below followed by detailed description of the preferred embodiments.

### BRIEF DESCRIPTION OF THE DRAWINGS

FIG. 1 shows an exterior view of the present invention.

FIG. 2 shows an exploded view of the present invention.

FIG. 3 shows a structural view depicting assembly of the present invention.

### DETAILED DESCRIPTION OF THE PREFERRED EMBODIMENTS

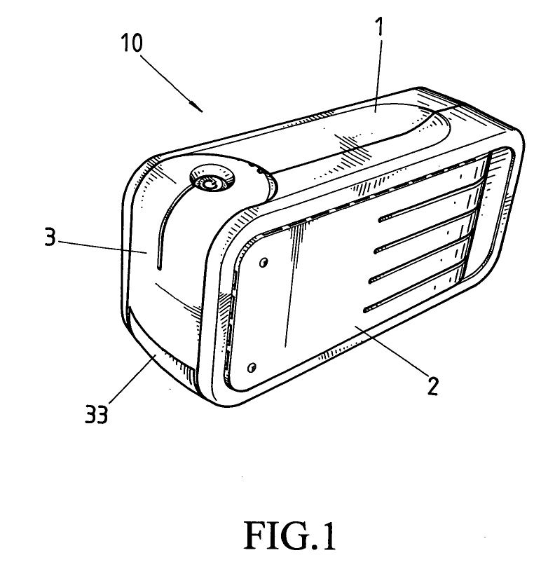

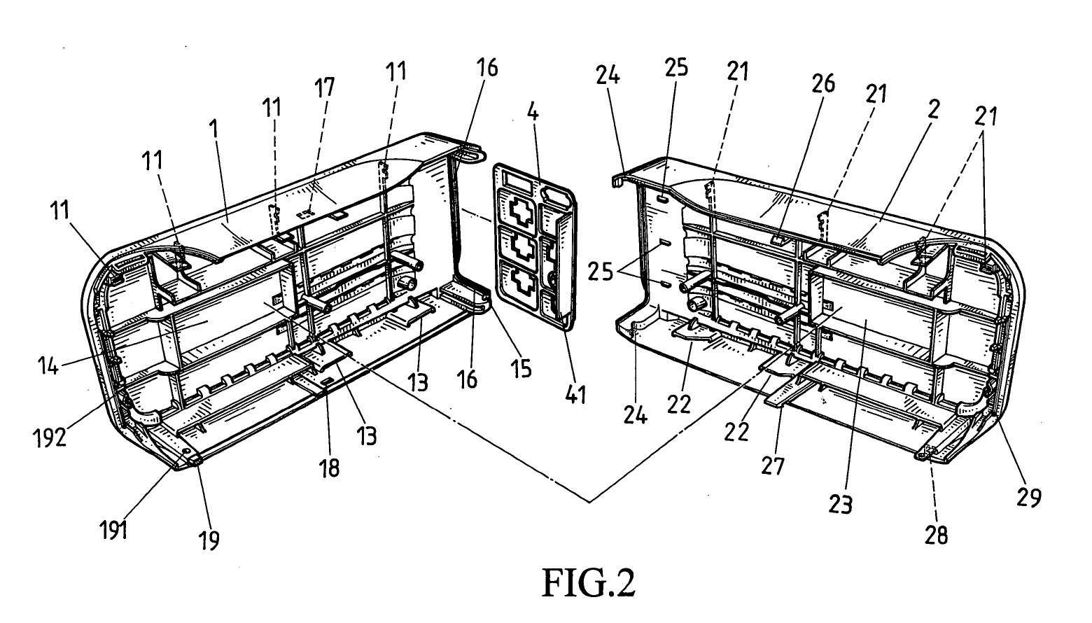

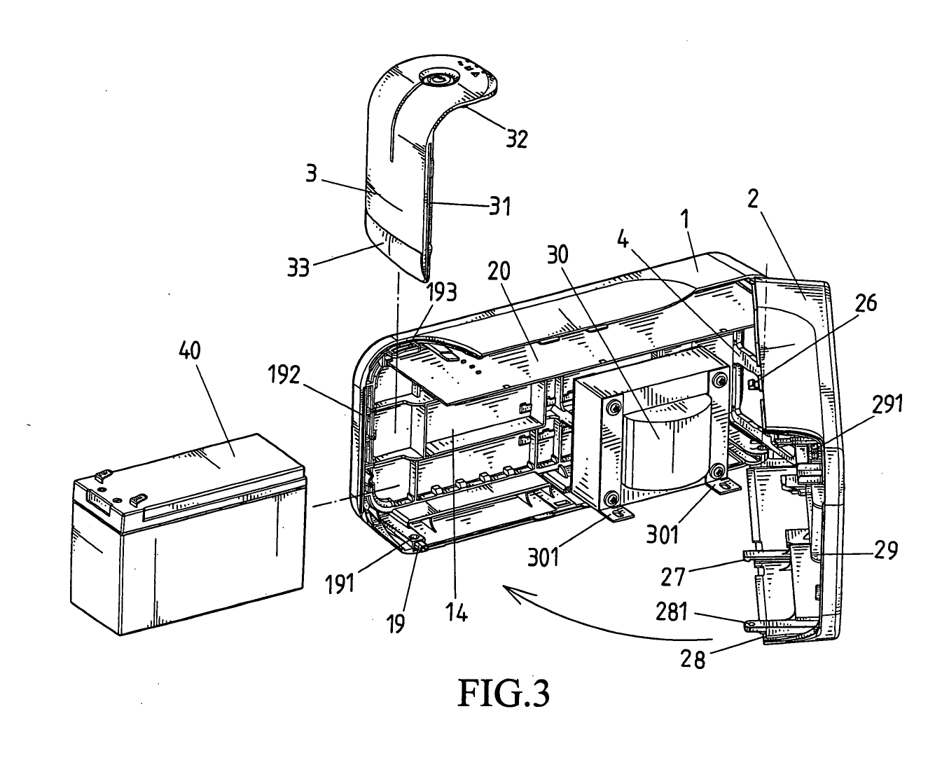

Referring to FIGS. 1, 2 and 3, which show a casing 10 of the present invention assembled from a left side panel 1, a right side panel 2, a front cover panel 3 and a rear cover panel 4. Upper edges of inner sides of the left and right side panels 1, 2 of the casing 10 are provided with PCB (printed circuit board) slots 11, 21 respectively, which provide for a PCB (printed circuit board) 20 to be clasped therein. Four feet mounts 301 of a bottom portion of a transformer 30 are positionally fixed within respective insert slots 13, 22 of bottom portions of the left and right side panels 1, 2 respectively. A 12V battery 40 is contained within battery compartments 14, 23 of the left and right side panels 1, 2 respectively. The present invention is characterized in that:

Arc-shaped hook slots 15, 24 are defined on upper and lower edges of rear sides of the left and right side panels 1, 2 respectively, which mutually hook together, thereby assembling the left and right side panels 1, 2 using a pivot-type catch fastening method. C-shaped slots 16 are defined on a rear edge of the left side panel 1, which provide for one end of the rear cover panel 4 to insert and be disposed therein. A block panel 41 at another end of the rear cover panel 4 is disposed on block pieces 25 of the right side panel 2.

A top inner edge of the left side panel 1 is provided with catch holes 17 that enable catch hooks 26 of a top end of the right side panel 2 to securely hook therein. Catch holes 18 of a bottom end of the left side panel 1 provide for catch hooks 27 of a bottom end of the right side panel 2 to securely hook therein. An insert piece 19 at a bottom end of a front edge of the left side panel 1 extends into an insert hole 28 at a bottom end of a front edge of the right side panel 2. A through hole 281 on a top portion of the insert hole 28 enables a screw bolt to pass therethrough and tighten into a bolt hole 191 of an inner edge of the insert piece 19 of the left side panel 1, thereby securing position of the left and right side panels 1, 2.

The aforementioned description discloses assembly of the left and right side panels 1, 2 and the rear cover panel 4. Prior to assembling the front cover panel 3, the battery 40 is first installed within the casing 10, and then the front cover panel 3 is assembled. Two sides of the front cover panel 3 are respectively provided with long catch slots 31, and front edges of the left and right side panels 1, 2 are provided with catch strips 192, 29 respectively. The front cover panel 3 is assembled by downwardly slotting the catch slots 31 onto the respective catch strips 192, 29. Two catch pieces 32 below a top end of the front cover panel 3 catch within catch holes 193, 291 of front top edges of the left and right side panels 1, 2 respectively, thereby completing assembly of the casing 10. An indent 33 at a lower portion of the front cover panel 3 provides for a user to upwardly push thereon using his hand, thereby removing the front cover panel 3 to facilitate replacing the battery.

In conclusion, after assembling the left and right side panels 1, 2 of the present invention using a pivot-type method, the rear cover panel 4 is then used to securely fasten together the left and right side panels 1, 2. The battery 40 is then installed, and the front cover panel 3 is slotted onto the front end of the casing 10, thereby completing assembly of the casing 10. Moreover, simply removing the front cover panel 3 facilitates replacement of the battery 40 in the casing structure 10.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. A casing structure for an uninterrupted power supply, comprising a left side panel, a right side panel, a front cover panel and a rear cover panel, upper edges of inner sides of the left and right side panels are respectively provided with PCB (printed circuit board) slots that provide for a PCB (printed circuit board) to be clasped therein, four feet mounts of a bottom portion of a transformer respectively insert within insert slots, a battery is contained within battery compartments of the left and right side panels; the casing structure for an uninterrupted power supply is characterized in that:
hook slots are respectively defined on upper and lower edges of rear sides of the left and right side panels, the hook slots mutually hook together to assemble the left and right side panels using a pivot-type method; two sides of the front cover panel are respectively provided with catch slots, and front edges of the left and right side panels are respectively provided with catch strips; the catch slots are used to slot onto the catch strips of the front cover panel, thereby completing assembly of the casing structure whereby simply removing the front cover panel facilitates replacing the battery.

2. The casing structure for an uninterrupted power supply according to claim 1, wherein C-shaped slots are defined on a rear edge of the left side panel, which provide for the rear cover panel to insert and be disposed therein.

3. The casing structure for an uninterrupted power supply according to claim 1, wherein a top inner edge of the left side panel is provided with catch holes that provide for catch hooks of a top end of the right side panel to securely hook therein.

4. The casing structure for an uninterrupted power supply according to claim 1, wherein catch holes of a bottom end of the left side panel provide for catch hooks of a bottom end of the right side panel to securely hook therein.

5. The casing structure for an uninterrupted power supply according to claim 1, wherein an insert piece at a bottom end of a front edge of the left side panel extends into an insert hole at a bottom end of a front edge of the right side panel

6. The casing structure for an uninterrupted power supply according to claim 1, wherein two catch pieces below a top end of the front cover panel respectively catch within catch holes of front top edges of the left and right side panels.
